(19) United States
(12) Patent Application Publication
(10) Pub. No.: US 2013/0208426 A1
(43) Pub. Date: Aug. 15, 2013

(54) SEMICONDUCTOR PACKAGE HAVING HEAT SPREADER AND METHOD OF FORMING THE SAME

(71) Applicants: Jae-Choon Kim, Incheon (KR); Heung-Kyu Kwon, Seongnam-si (KR); Young-Deuk Kim, Suwon-si (KR); Ji-Chul Kim, Yongin-si (KR); Jae-Bum Byun, Suwon-si (KR); Ho-Geon Song, Suwon-si (KR); Eun-Seok Cho, Suwon-si (KR)

(72) Inventors: Jae-Choon Kim, Incheon (KR); Heung-Kyu Kwon, Seongnam-si (KR); Young-Deuk Kim, Suwon-si (KR); Ji-Chul Kim, Yongin-si (KR); Jae-Bum Byun, Suwon-si (KR); Ho-Geon Song, Suwon-si (KR); Eun-Seok Cho, Suwon-si (KR)

(73) Assignee: SAMSUNG ELECTRONICS CO., LTD., Suwon-si (KR)

(21) Appl. No.: 13/611,605

(22) Filed: Sep. 12, 2012

(30) Foreign Application Priority Data
Feb. 15, 2012 (KR) 10-2012-0015514

(51) Int. Cl. H05K 7/20

(52) U.S. Cl. 361/717

(57) ABSTRACT

A semiconductor chip and a first heat dissipation pattern are mounted on a substrate. The first heat dissipation pattern has an opening therein and exposes the semiconductor chip therethrough. A second heat dissipation pattern including a thermal interface material (TIM) is interposed between a side surface of the semiconductor chip and the first heat dissipation pattern.

### CROSS-REFERENCE TO RELATED APPLICATION

This application claims priority under 35 U.S.C. §119 to Korean Patent Application No. 10-2012-0015514, filed on Feb. 15, 2012 in the Korean Intellectual Property Office (KIPO), the disclosure of which is hereby incorporated by reference in its entirety.

### BACKGROUND

1. Field

Example embodiments of the inventive concepts relate to a thin semiconductor package having a heat spreader and a method of forming the same.

2. Description of Related Art

Various methods have been studied to reduce the thickness of a semiconductor package and efficiently dissipate heat generated in the semiconductor package.

### SUMMARY

Example embodiments of the inventive concepts provide a semiconductor package capable of reducing the thickness and efficiently dissipating heat.

According to example embodiments, a semiconductor package includes a semiconductor chip mounted on a substrate, a first heat dissipation pattern mounted on the substrate, the first heat dissipation pattern having an opening and the opening is configured to expose the semiconductor chip, and a second heat dissipation pattern having a thermal interface material (TIM) is between a side surface of the semiconductor chip and the first heat dissipation pattern.

According to example embodiments, a top surface of the second heat dissipation pattern may have a relatively high mean curvature compared to a top surface of the semiconductor chip.

According to example embodiments, a top surface of the second heat dissipation pattern may be either higher or lower than a top surface of the semiconductor chip.

According to example embodiments, the first heat dissipation pattern may be thicker than the semiconductor chip. A top surface of the first heat dissipation pattern may be higher than a top surface of the semiconductor chip.

According to example embodiments, the first heat dissipation pattern may include at least one of a through-hole and a groove. The opening of the first heat dissipation pattern may be in communication with an outside of the first heat dissipation pattern via the through-hole and/or the groove.

According to example embodiments, the semiconductor chip may include a first side surface, a second side surface facing the first side surface, and a heating circuit close to the first side surface. A first gap formed between the first side surface and the first heat dissipation pattern may be narrower than a second gap formed between the second side surface and the first heat dissipation pattern.

According to example embodiments, the semiconductor package may further include a filler formed between the substrate and the semiconductor chip and an internal terminal passing through the filler and electrically connecting the semiconductor chip to the substrate. The internal terminal may include a solder ball or a conductive bump. The second heat dissipation pattern may be in contact with the filler.

According to example embodiments, the second heat dissipation pattern may extend between the substrate and the semiconductor chip. The internal terminal may pass through the second heat dissipation pattern and electrically connect the semiconductor chip to the substrate.

According to example embodiments, the second heat dissipation pattern may extend between the first heat dissipation pattern and the substrate.

According to example embodiments, a semiconductor package includes a semiconductor chip mounted on a substrate, an encapsulant on the substrate, the encapsulant configured to cover a side surface of the semiconductor, a first heat dissipation pattern mounted on the semiconductor chip and the encapsulant, and a second heat dissipation pattern having a thermal interface material (TIM) formed between the semiconductor chip and the first heat dissipation pattern and between the encapsulant and the first heat dissipation pattern.

According to example embodiments, the second heat dissipation pattern may be in contact with the semiconductor chip and the first heat dissipation pattern.

According to example embodiments, the second heat dissipation pattern may have a first thickness between the semiconductor chip and the first heat dissipation pattern, and a second thickness between the encapsulant and the first heat dissipation pattern. The second thickness may be greater than the first thickness.

According to example embodiments, a top surface of the encapsulant may be lower than a top surface of the semiconductor chip. The second heat dissipation pattern may be in contact with a side surface of the semiconductor chip.

According to example embodiments, the first heat dissipation pattern may include an opening arranged on the semiconductor chip. The second heat dissipation pattern may extend to an inside of the opening.

According to example embodiments, a semiconductor package includes a semiconductor chip on a substrate, a first heat dissipation pattern on the substrate, and a second heat dissipation pattern between the semiconductor chip and the first heat dissipation pattern, the second heat dissipation pattern including a thermal interface material (TIM).

According to example embodiments, the first heat dissipation pattern may include an opening, the opening configured to expose the semiconductor chip. The opening may include a plurality of openings.

According to example embodiments, the second heat dissipation pattern may extend at least one of between the substrate and the semiconductor chip and between the substrate and the first heat dissipation pattern.

According to example embodiments, a top surface of the first heat dissipation pattern may be either higher or lower than a top surface of the semiconductor chip.

According to example embodiments, a bottom surface of the first heat dissipation pattern may be lower than a bottom surface of the semiconductor chip. The bottom surface of the first heat dissipation pattern faces the substrate and is opposite to the top surface of the first heat dissipation pattern. The bottom surface of the semiconductor chip faces the substrate and is opposite to the top surface of the semiconductor chip.

### BRIEF DESCRIPTION OF THE DRAWINGS

The foregoing and other features and advantages of the inventive concepts will become more apparent from the detailed description of example embodiments with reference to the accompanying drawings, in which:

FIG. 1 is a cross-sectional view describing a semiconductor package in accordance with example embodiments of the inventive concepts;

FIGS. 2 to 6 are enlarged views illustrating a part of the semiconductor package shown in FIG. 1;

FIG. 7 is a cross-sectional view describing an another semiconductor package in accordance with example embodiments of the inventive concepts;

FIGS. 8 and 9 are perspective views illustrating some components of the semiconductor package shown in FIG. 7;

FIGS. 10 to 26 are cross-sectional views describing another semiconductor packages in accordance with example embodiments of the inventive concepts;

FIGS. 27 to 29 are cross-sectional views illustrating a method of manufacturing a semiconductor package in accordance with example embodiments of the inventive concepts; and

FIGS. 30 and 31 are system block diagrams illustrating electronic devices in accordance with example embodiments of the inventive concepts.

It should be noted that these figures are intended to illustrate the general characteristics of structures, methods, and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE EMBODIMENTS

Various embodiments will now be described more fully with reference to the accompanying drawings in which some example embodiments are shown. The inventive concepts may, however, be embodied in different forms and should not be construed as limited to the example embodiments set forth herein. Rather, the example embodiments are provided so that this disclosure is thorough and complete and fully conveys the inventive concepts to those skilled in the art.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element's or feature's relationship to another elements or features as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented rotated 90 degrees or at other orientations and the spatially relative descriptors used herein interpreted accordingly.

The terminology used herein is for the purpose of describing particular embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments and intermediate structures. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms including technical and scientific terms used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

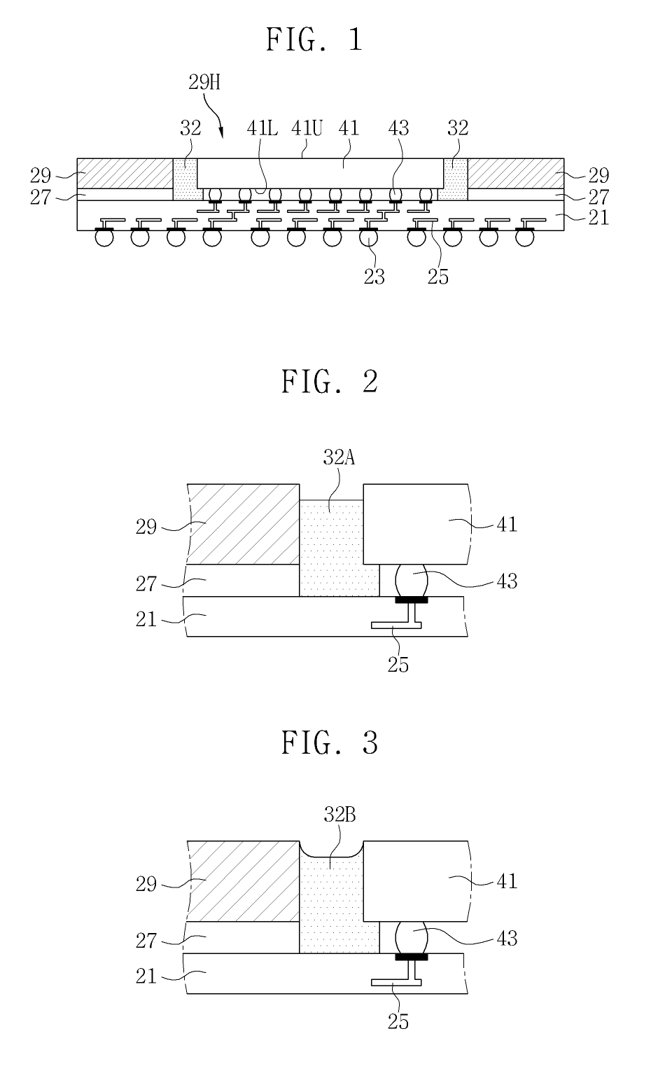

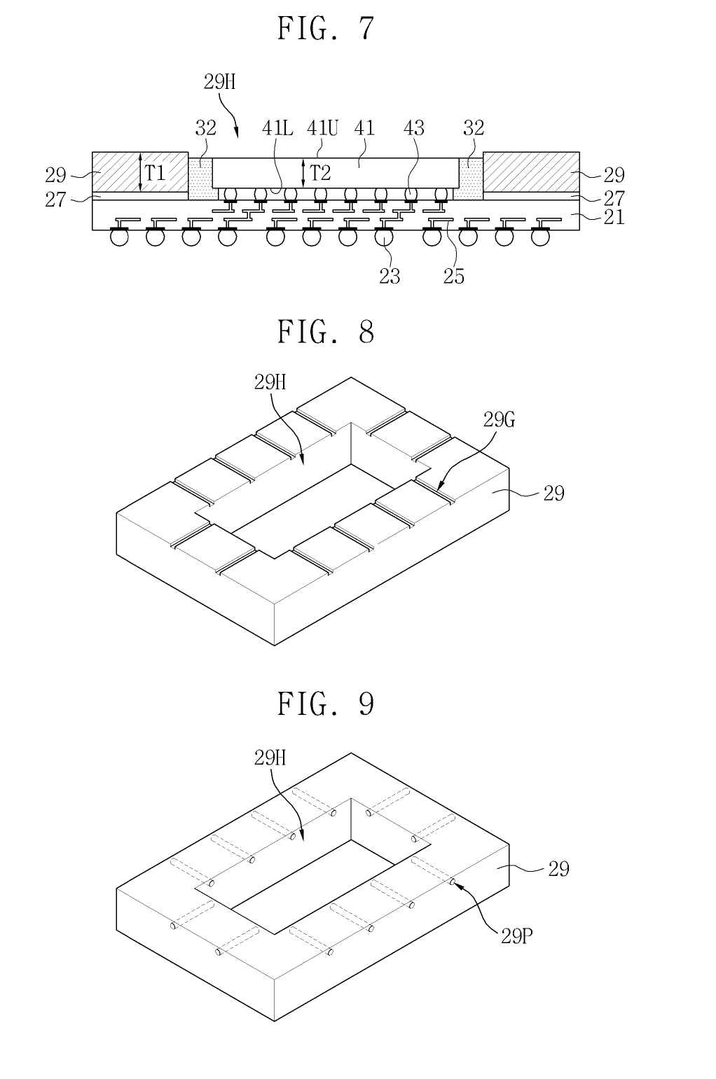

FIGS. 1, 7, and 10 to 26 are cross-sectional views describing semiconductor packages in accordance with example embodiments of the inventive concepts, FIGS. 2 to 6 are enlarged views showing a part of the semiconductor package shown in FIG. 1, and FIGS. 8 and 9 are perspective views illustrating some components of the semiconductor package shown in FIG. 7.

Referring to FIG. 1, a first semiconductor chip 41 and a first heat dissipation pattern 29 may be mounted on a substrate 21. Also, a second heat dissipation pattern 32 having a thermal interface material (TIM) may be formed between the first semiconductor chip 41 and the first heat dissipation pattern 29. The second heat dissipation pattern 32 may be in contact with a side surface of the first semiconductor chip 41 and the first heat dissipation pattern 29. The first heat dissipation pattern 29 and the second heat dissipation pattern 32 may be referred to as a heat spreader, a heat slug, or a heat sink. Also, the first heat dissipation pattern 29 may be referred to as an external heat dissipation pattern and the second heat dissipation pattern 32 as an internal heat dissipation pattern.

The substrate 21 may be a rigid printed circuit board, a flexible printed circuit board, or a rigid-flexible printed circuit board. In addition, the substrate 21 may be a multi-layer printed circuit board. The substrate 21 may include a plurality of internal wirings 25. External terminals 23 may be formed on one side of the substrate 21. The external terminals 23 may include a solder ball, a conductive bump, a pin grid array, a lead grid array, a conductive tap, or a combination thereof. The external terminals 23 may be connected to the internal wirings 25.

The first semiconductor chip 41 may be a logic chip. The first semiconductor chip 41 may include a first surface 41L and a second surface 41U. The first surface 41L may face the substrate 21 and the second surface 41U may be parallel to the first surface 41L. Internal terminals 43 may be formed between the substrate 21 and the first surface 41L. The internal terminals 43 may include a solder ball, a conductive bump, a conductive tap, or a combination thereof. The first semiconductor chip 41 may be electrically connected to the external terminals 23 via the internal terminals 43 and the internal wirings 25. The first semiconductor chip 41, the internal terminals 43, and the substrate 21 may form a flip-chip package.

The first heat dissipation pattern 29 may be attached onto the substrate 21 using an adhesive film 27. The first heat dissipation pattern 29 may include copper, aluminum, an alloy, or a material having high thermal conductivity. The first heat dissipation pattern 29 may include an opening 29H larger than the first semiconductor chip 41. The first semiconductor chip 41 may be arranged in the opening 29H. For example, the second surface 41U of the first semiconductor chip 41 may be exposed in the opening 29H, and side surfaces of the first semiconductor chip 41 may face the first heat dissipation pattern 29. The top surface of the first heat dissipation pattern 29 may be located substantially at the same level as the second surface 41U.

The second heat dissipation pattern 32 may include a thermal interface material (TIM) having high thermal conductivity. The second heat dissipation pattern 32 may be formed by hardening a liquid or paste type of the TIM. The second heat dissipation pattern 32 may be limitedly formed between the first heat dissipation pattern 29 and the first semiconductor chip 41. The second heat dissipation pattern 32 may be in contact with the side surfaces of the first semiconductor chip 41, the adhesive film 27, or the first heat dissipation pattern 29. In addition, the second heat dissipation pattern 32 may partly extend between the first semiconductor chip 41 and the substrate 21. The top surfaces of the first semiconductor chip 41, the first heat dissipation pattern 29, and the second heat dissipation pattern 32 may be substantially at the same level.

In some example embodiments, the second heat dissipation pattern 32 may be formed using a thermally conductive adhesive, a thermally conductive encapsulant, a thermally conductive compound, or a thermally conductive gel. For example, the second heat dissipation pattern 32 may include an underfill material having TIM. The second heat dissipation pattern 32 may be in tight contact with the first semiconductor chip 41 and the first heat dissipation pattern 29, and may have excellent heat conductivity.

According to example embodiments of the inventive concepts, the second heat dissipation pattern 32 may function to effectively transfer heat generated from the first semiconductor chip 41 to the first heat dissipation pattern 29. Some of the heat generated from the first semiconductor chip 41 may be dissipated through the second surface 41U. In some example embodiments, the first heat dissipation pattern 29 and the second surface 41U of the first semiconductor chip 41 may contact a case of an electronic device or adhere to the backside of a display device. Because the first heat dissipation pattern 29 is disposed on the side surface of the first semiconductor chip 41, the thickness of the semiconductor package can be reduced or minimized. Therefore, a semiconductor package effective in heat dissipation can be realized lighter, thinner, shorter, and/or smaller.

Referring to FIG. 2, the second heat spreader 32A may be formed at a lower level than the top surfaces of the first semiconductor chip 41 and the first heat dissipation pattern 29.

Referring to FIG. 3, the top surface of the second heat dissipation pattern 32B may have a concave shape. The top surface of the second heat dissipation pattern 32B may have a profile that gradually rises toward the side surfaces of the first semiconductor chip 41 and the first heat dissipation pattern 29. The top surface of the second heat dissipation pattern 32B may have a higher mean curvature than the top surface of the first semiconductor chip 41.

The mean curvature of a surface is an extrinsic measure of curvature (reciprocal of its radius) that comes from differential geometry. All curves on the surface S passing through a point P has an associated curvature Ki given at the point P. Of those curvatures Ki, at least one is characterized as maximal k1 and one as minimal k2, and these two curvatures k1 and k2 are known as the principal curvatures of the surface S. The mean curvature H at the point P is the average of the principal curvatures, i.e., H=1/2(k1+k2). Accordingly, the mean curvature of a plane is zero.

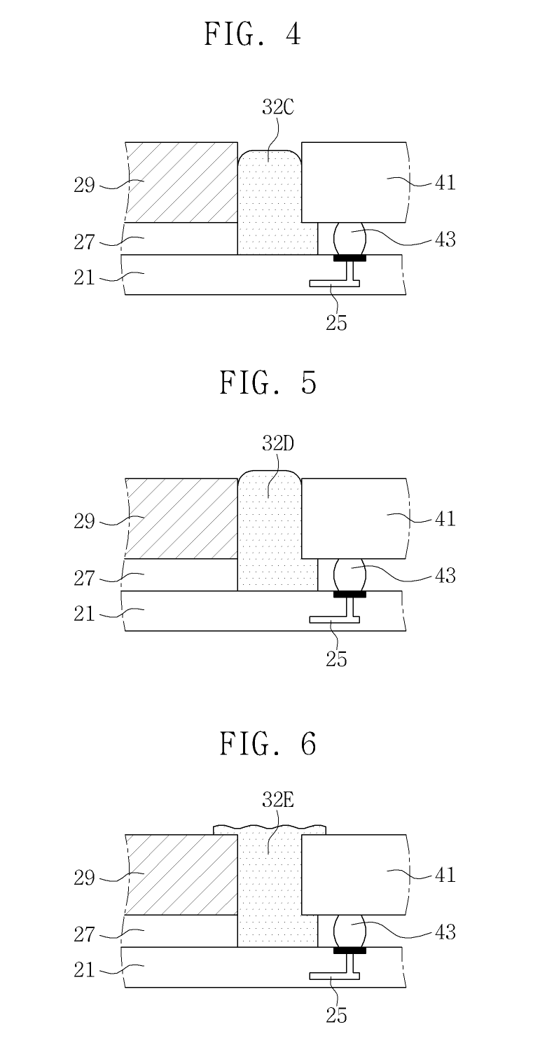

Referring to FIG. 4, the top surface of the second heat dissipation pattern 32C may have a convex shape. The second heat dissipation pattern 32C may have a profile that gradually falls toward the side surfaces of the first semiconductor chip 41 and first heat dissipation pattern 29. The top surface of the second heat dissipation pattern 32C may have a higher mean curvature than the top surface of the first semiconductor chip 41.

Referring to FIG. 5, the top surface of the second heat dissipation pattern 32D may be formed at a higher level than the first semiconductor chip 41 and the first heat dissipation pattern 29. The second heat dissipation pattern 32D may protrude up between the first semiconductor chip 41 and the first heat dissipation pattern 29. The second heat dissipation pattern 32D may function to protect the first semiconductor chip 41 from shock.

Referring to FIG. 6, the top surface of the second heat dissipation pattern 32E may be formed at a higher level than the first semiconductor chip 41 and the first heat dissipation pattern 29. The second heat dissipation pattern 32E may partly cover the top surfaces of the first semiconductor chip 41 and first heat dissipation pattern 29. The top surface of the second heat dissipation pattern 32E may have an uneven profile. The top surface of the second heat dissipation pattern 32E may have a higher mean curvature than the top surface of the first semiconductor chip 41. The second heat dissipation pattern 32E may function to protect the first semiconductor chip 41 from shock. The second heat dissipation pattern 32E may function to effectively dissipate heat generated from the first semiconductor chip 41.

Referring to FIG. 7, the first heat dissipation pattern 29 and the first semiconductor chip 41 may have a first thickness T1 and a second thickness T2, respectively. The first thickness T1 may be greater than the second thickness T2. A bottom of the first heat dissipation pattern 29 may be located at a lower level than the first surface 41L of the first semiconductor chip 41. The top surface of the first heat dissipation pattern 29 may be located at a higher level than the second surface 41U of the first semiconductor chip 41. The second surface 41U of the first semiconductor chip 41 may be exposed in the opening 29H of the first heat dissipation pattern 29. The first heat dissipation pattern 29 may function to protect the first semiconductor chip 41 from shock.

Referring to FIG. 8, the first heat dissipation pattern 29 may include a plurality of grooves 29G formed on the top surface thereof.

Referring to FIG. 9, the first heat dissipation pattern 29 may include a plurality of through-holes 29P. The through-holes 29P may be formed close to the top surface of the first heat dissipation pattern 29. The opening 29H of the first heat dissipation pattern 29 may be connected to the outside of the first heat dissipation pattern 29 via the grooves 29G illustrated in FIG. 8 and/or the through-holes 29P.

In some example embodiments of the inventive concepts, the first heat dissipation pattern 29 may include both the grooves 29G and through-holes 29H.

The grooves 29G and through-holes 29H may function as an air path. When the first heat dissipation pattern 29 and the second surface 41U of the first semiconductor chip 41 are attached to a case of an electronic device or a backside of a display device, heat emitted from the second surface 41U of the first semiconductor chip 41 may be dissipated out of the first heat dissipation pattern 29 via the grooves 29G and/or the through-holes 29P.

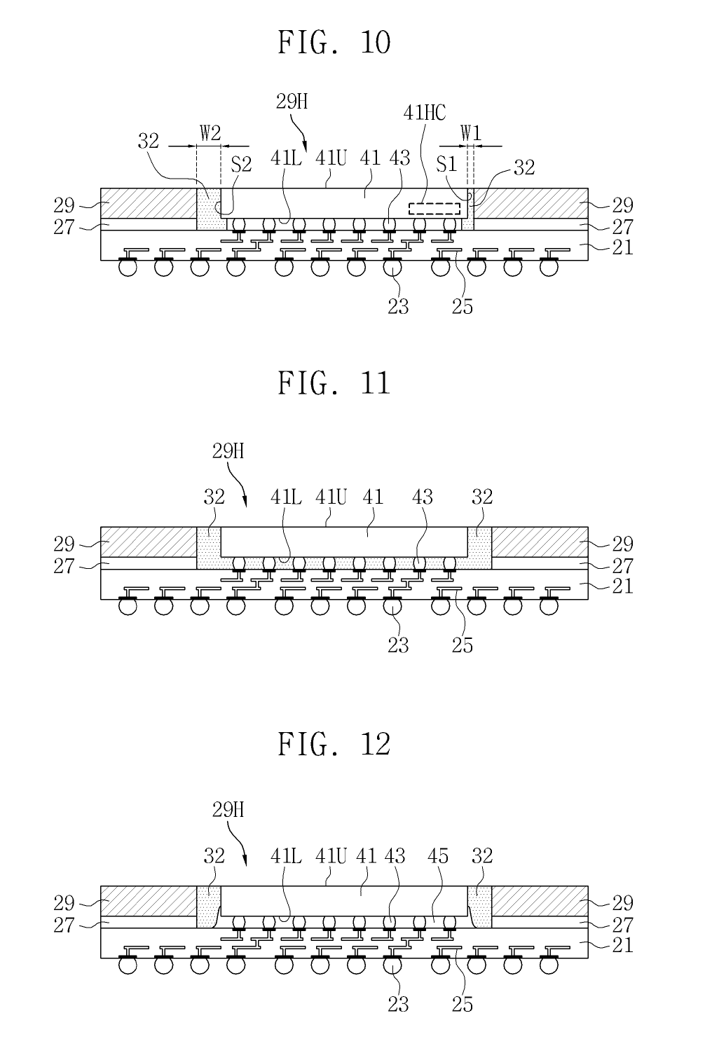

Referring to FIG. 10, the first semiconductor chip 41 may include a first side surface S1 and a second side surface S2. The second side surface S2 may be opposite to the first side surface S1. In addition, the first semiconductor chip 41 may include a heating circuit 41HC. The heating circuit 41HC may be concentrated in a part of the first semiconductor chip 41. For example, the heating circuit 41HC may be formed relatively close to the first side surface S1 of the first semiconductor chip 41. The second heat dissipation pattern 32 may have a first width W1 between the first side surface S1 and the first heat dissipation pattern 29, and the second heat dissipation pattern 32 may have a second width W2 between the second side surface S2 and the first heat dissipation pattern 29. The first width W1 may be narrower than the second width W2. Accordingly, the first heat dissipation pattern 29 may be formed relatively close to the heating circuit 41HC. Because the first heat dissipation pattern 29 is formed relatively close to the heating circuit 41HC, local heating of the first semiconductor chip 41 can be reduced or prevented more effectively.

Referring to FIG. 11, the second heat dissipation pattern 32 may fill a space between the first semiconductor chip 41 and the substrate 21. The internal terminals 43 may pass through the second heat dissipation pattern 32 and electrically connect the first semiconductor chip 41 to the substrate 21.

Referring to FIG. 12, a filler 45 may be formed between the first semiconductor chip 41 and the substrate 21. The filler 45 may include an underfill material. The filler 45 may fill the space between the first semiconductor chip 41 and the substrate 21, and partially cover the side surface of the first semiconductor chip 41. The second heat dissipation pattern 32 may be formed between the first semiconductor chip 41 and the first heat dissipation pattern 29, and may contact the filler 45 and the adhesive film 27.

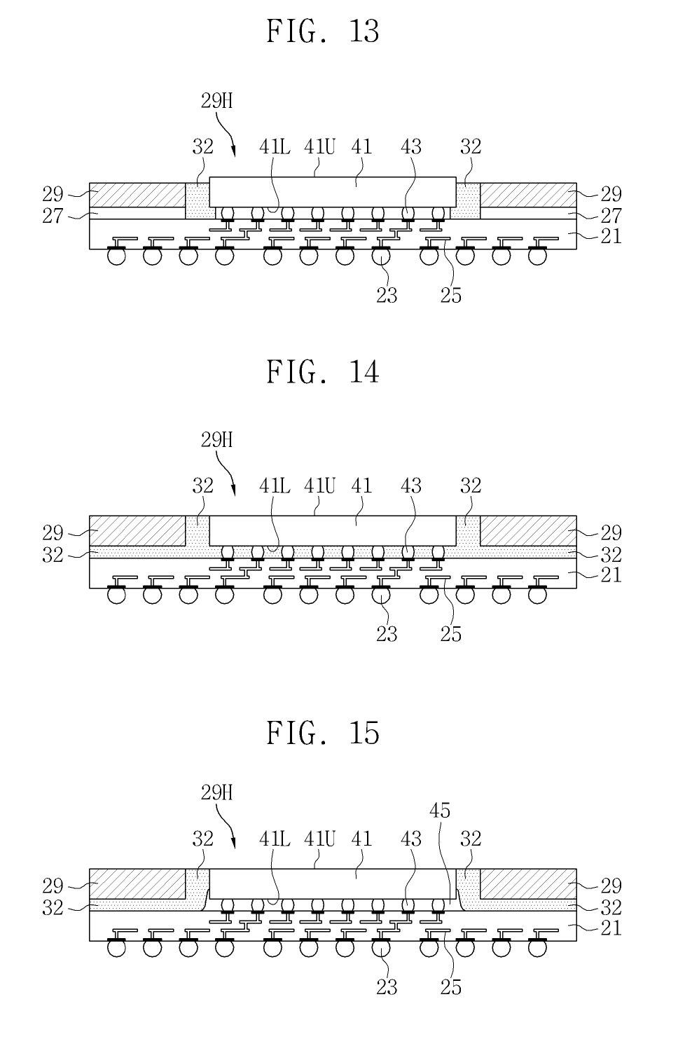

Referring to FIG. 13, the first heat dissipation pattern 29 may be thinner than the first semiconductor chip 41. The first heat dissipation pattern 29 may be formed at a lower level than the top surface of the first semiconductor chip 41.

Referring to FIG. 14, the second heat dissipation pattern 32 may fill a space between the first semiconductor chip 41 and the first heat dissipation pattern 29, and extend between the first heat dissipation pattern 29 and the substrate 21, and between the first semiconductor chip 41 and the substrate 21.

Referring to FIG. 15, the second heat dissipation pattern 32 may fill the space between the first semiconductor chip 41 and the first heat dissipation pattern 29, and extend between the first heat dissipation pattern 29 and the substrate 21. A filler 45 may be formed between the first semiconductor chip 41 and the substrate 21. The second heat dissipation pattern 32 may be in contact with the filler 45.

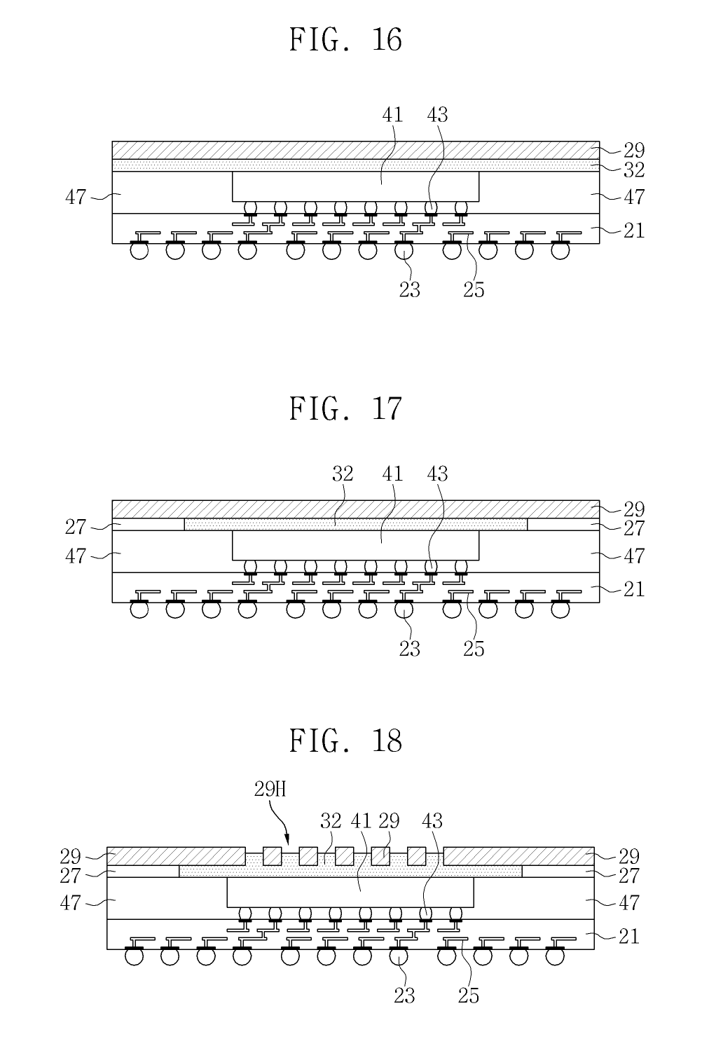

Referring to FIG. 16, the first semiconductor chip 41 may be mounted on the substrate 21 using the internal terminals 43. An encapsulant 47 may be formed on the substrate 21 covering the side surfaces of the first semiconductor chip 41. The encapsulant 47 may include a molding compound. The top surface of the first semiconductor chip 41 and the encapsulant 47 may be substantially located on the same plane. The encapsulant 47 may fill a space between the first semiconductor chip 41 and the substrate 21. The internal terminals 43 may pass through the encapsulant 47 and electrically connect the first semiconductor chip 41 to the substrate 21.

The second heat dissipation pattern 32 and the first heat dissipation pattern 29 may be formed in order, on the first semiconductor chip 41 and the encapsulant 47. The second heat dissipation pattern 32 may be in contact with the first heat dissipation pattern 29, the first semiconductor chip 41, and the encapsulant 47. The top surface of the first heat dissipation pattern 29 may be exposed. The top surface of the first heat dissipation pattern 29 may be parallel to the substrate 21.

Referring to FIG. 17, the first heat dissipation pattern 29 may be attached to the encapsulant 47 using an adhesive film 27. The second heat dissipation pattern 32 may be limitedly formed on at least one of the semiconductor chip 41 and the encapsulant 47, at an area where the adhesive film 27 is not formed. The second heat dissipation pattern 32 may be in contact with the first heat dissipation pattern 29, the adhesive film 27, the first semiconductor chip 41, and/or the encapsulant 47.

Referring to FIG. 18, the first heat dissipation pattern 29 may include a plurality of openings 29H arranged on the first semiconductor chip 41. The second heat dissipation pattern 32 may be formed at least partially filling in the openings 29H.

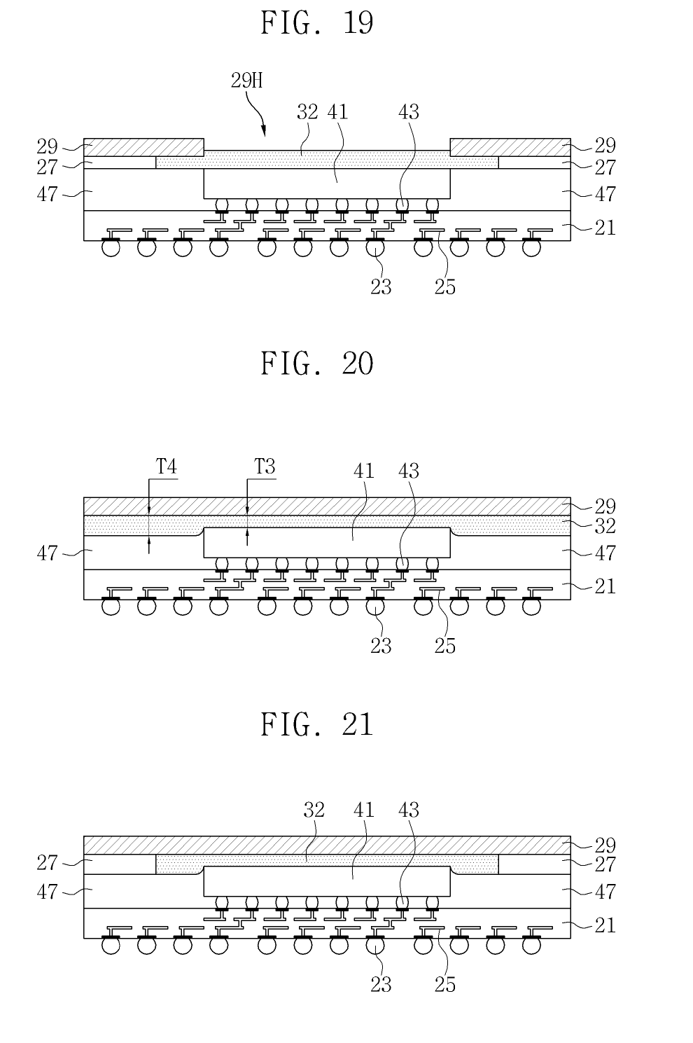

Referring to FIG. 19, the first heat dissipation pattern 29 may include an opening 29H arranged on the first semiconductor chip 41. The opening 29H may be the same as or larger than the top surface of the first semiconductor chip 41. The second heat dissipation pattern 32 may be formed in the opening 29H. The second heat dissipation pattern 32 may also be formed under the first heat dissipation pattern 29.

Referring to FIG. 20, the encapsulant 47 may be formed at a lower level than the top surface of the first semiconductor chip 41. The encapsulant 47 may have a profile that gradually rises toward the side surface of the first semiconductor chip 41. The second heat dissipation pattern 32 may have a third thickness T3 between the first semiconductor chip 41 and the first heat dissipation pattern 29, and a fourth thickness T4 between the encapsulant 47 and the first heat dissipation pattern 29. The fourth thickness T4 may be greater than the third thickness T3. The second heat dissipation pattern 32 may be in contact with the side surface of the first semiconductor chip 41.

Referring to FIG. 21, the encapsulant 47 may be formed at a lower level than the top surface of the first semiconductor chip 41. The first heat dissipation pattern 29 may be attached to the encapsulant 47 using the adhesive film 27. The second heat dissipation pattern 32 may be limitedly formed on at least one of the semiconductor chip 41 and the encapsulant 47, at an area where the adhesive layer 27 is not formed.

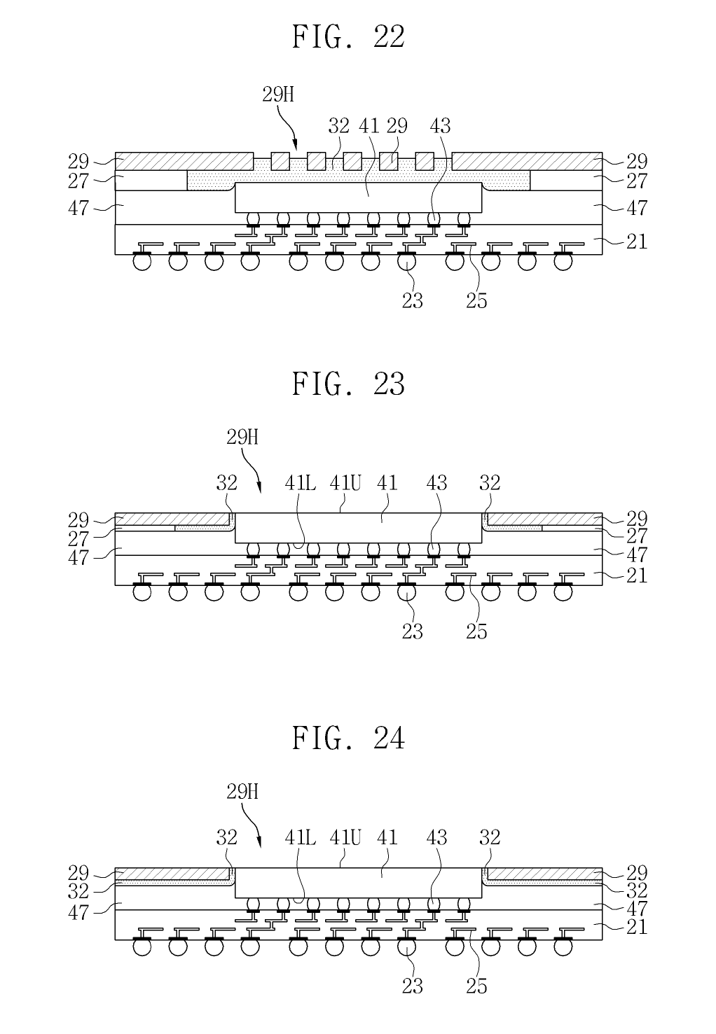

Referring to FIG. 22, the encapsulant 47 may be formed at a lower level than the top surface of the first semiconductor chip 41. The first heat dissipation pattern 29 may include a plurality of openings 29H arranged on the first semiconductor chip 41. The second heat dissipation pattern 32 may extend to the insides of the openings 29H.

Referring to FIG. 23, the first heat dissipation pattern 29 may include an opening 29H having larger width than the first semiconductor chip 41. The first heat dissipation pattern 29 may be attached to the encapsulant 47 using the adhesive film 27. The second heat dissipation pattern 32 may be formed between the side surface of the first semiconductor chip 41 and the first heat dissipation pattern 29, and between the encapsulant 47 and the first heat dissipation pattern 29. The second surface 41U of the first semiconductor chip 41 may be exposed.

Referring to FIG. 24, the second heat dissipation pattern 32 may be formed between the side surface of the first semiconductor chip 41 and the first heat dissipation pattern 29, and between the encapsulant 47 and the first heat dissipation pattern 29.

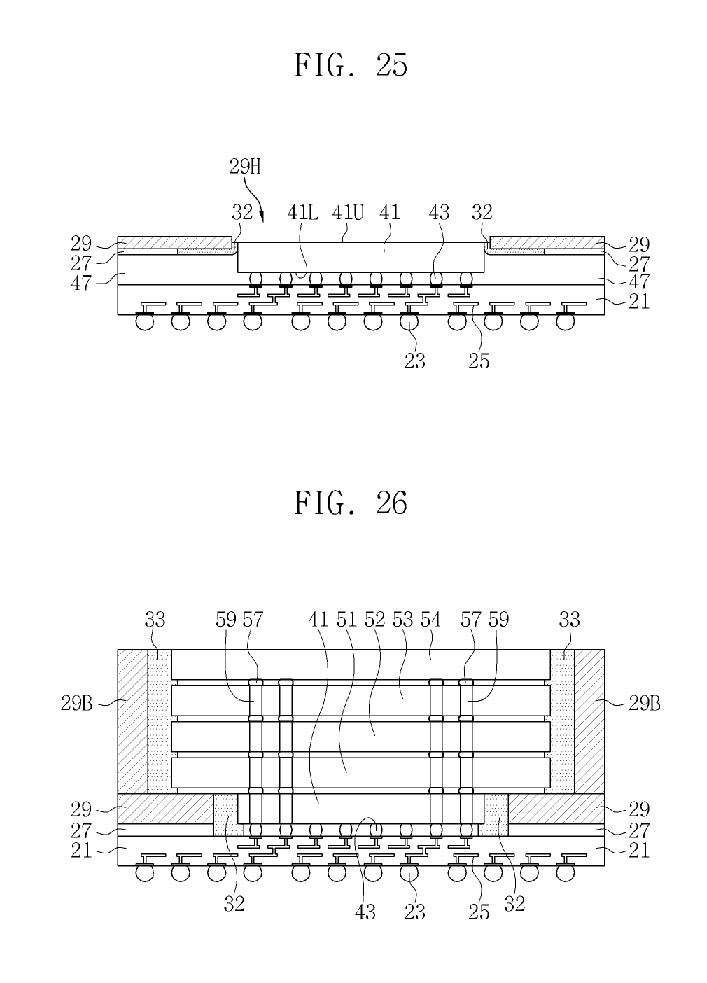

Referring to FIG. 25, the top surface of the first heat dissipation pattern 29 may be formed at a higher level than the first semiconductor chip 41.

Referring to FIG. 26, the first semiconductor chip 41 and the first heat dissipation pattern 29 may be mounted on the substrate 21. A second heat dissipation pattern 32 having a thermal interface material (TIM) may be formed between the first semiconductor chip 41 and the first heat dissipation pattern 29. Second to fifth semiconductor chips 51, 52, 52, and 54 may be mounted on the first semiconductor chip 41. The second to fifth semiconductor chips 51, 52, 52, and 54 may be connected to the internal terminals 43 via through-electrodes 59 and upper terminals 57.

A third heat dissipation pattern 29B facing the second to fifth semiconductor chips 51, 52, 53, and 54 may be formed on the first heat dissipation pattern 29. A fourth heat dissipation pattern 33 may be formed between the third heat dissipation pattern 29B and the second to fifth semiconductor chips 51, 52, 53, and 54. The third heat dissipation pattern 29B may include the same material as the first heat dissipation pattern 29, and the fourth heat dissipation pattern 33 may include the same material as the second heat dissipation pattern 32.

The upper terminals 57 may include a solder ball, a conductive bump, a conductive tap, or a combination thereof. The second to fifth semiconductor chips 51, 52, 53, 54 may have a larger width than the first semiconductor chip 41. The second to fifth semiconductor chips 51, 52, 53, and 54 may include a non-volatile memory device, a volatile memory device, or a combination thereof. For example, one of the second to fifth semiconductor chips 51, 52, 53, and 54 may include a buffer chip such as DRAM or SRAM, and others of the second to fifth semiconductor chips 51, 52, 53, and 54 may include a memory chip such as NAND flash.

The third heat dissipation pattern 29B may be in contact with the first heat dissipation pattern 29. The third heat dissipation pattern 29B may be integrated with the first heat dissipation pattern 29.

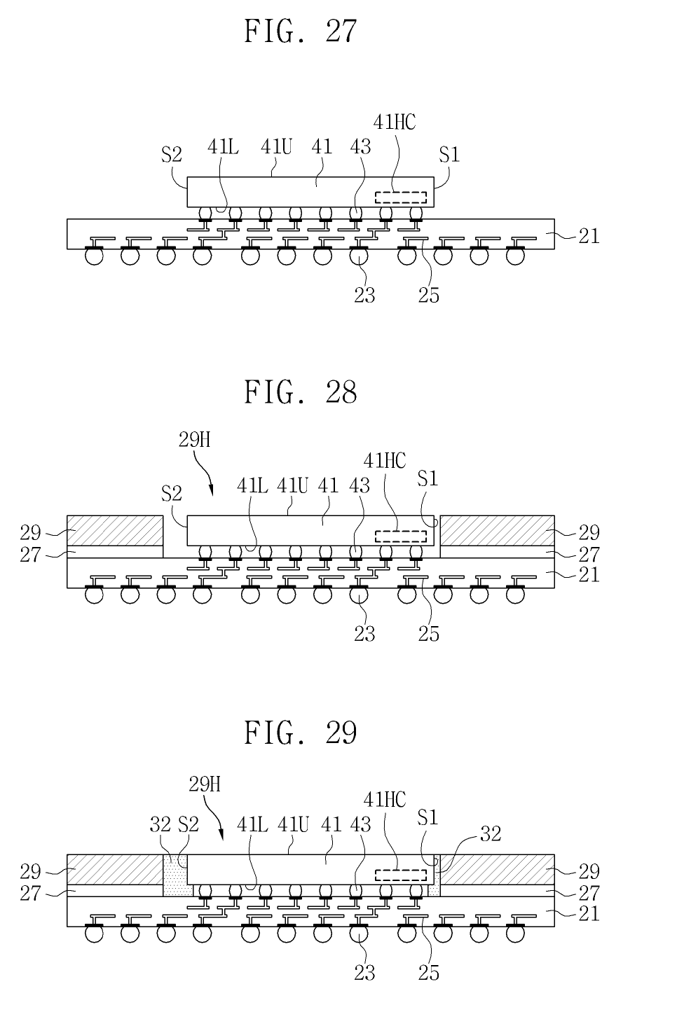

FIGS. 27 to 29 are cross-sectional views illustrating a manufacturing method of a semiconductor package in accordance with example embodiments of the inventive concepts.

Referring to FIG. 27, a first semiconductor chip 41 may be mounted on a substrate 21 using internal terminals 43. The first semiconductor chip 41 may include a first side surface 51 and a second side surface S2. The first semiconductor chip 41 may include a heating circuit 41HC formed relatively close to the first side surface 51. The first semiconductor chip 41 may generate heat of relatively high temperature near the heating circuit 41HC under conventional operation conditions.

Referring to FIG. 28, a first heat dissipation pattern 29 may be mounted on the substrate 21 using an adhesive film 27. The first heat dissipation pattern 29 may include an opening 29H larger than the first semiconductor chip 41. The first semiconductor chip 41 may be arranged to be exposed in the opening 29H. The first heat dissipation pattern 29 may be attached relatively close to the heating circuit 41HC. The adhesive film may be a tape including an adhesive.

Referring to FIG. 29, a second heat dissipation pattern 32 having a thermal interface material (TIM) may be formed between the first heat dissipation patterns 29. The second heat dissipation pattern 32 may be in contact with a side surface of the first semiconductor chip 41 and with the first heat dissipation pattern 29. The second heat dissipation pattern 32 may be formed by filling a space between the first semiconductor chip 41 and the first heat dissipation pattern 29 with a liquid or paste type of TIM, and then hardening the TIM.

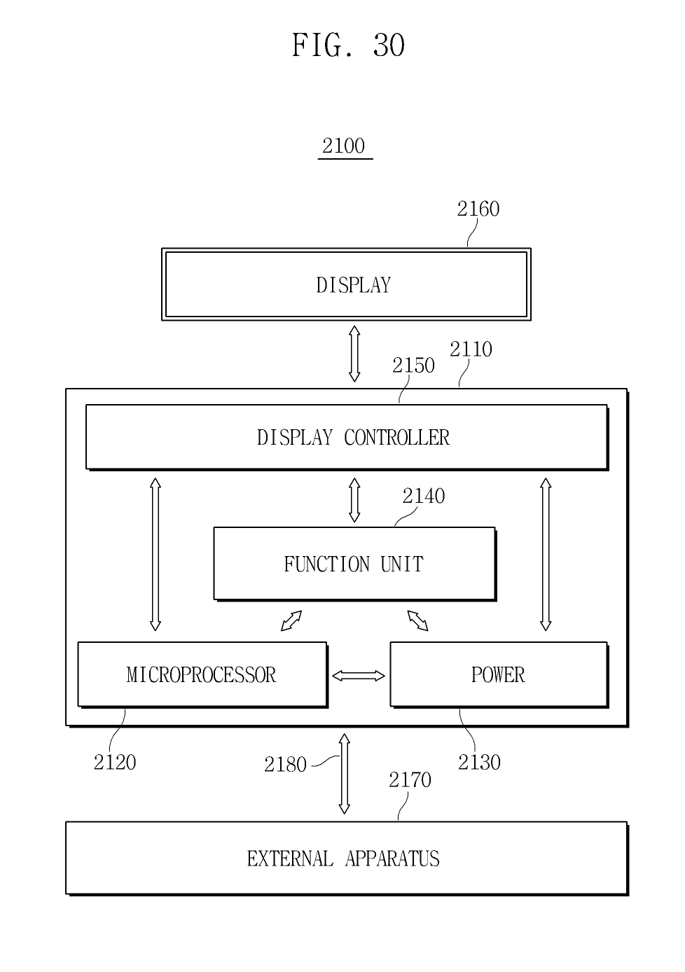

FIG. 30 is a system block diagram illustrating an electronic device in accordance with example embodiments of the inventive concepts.

Referring to FIG. 30, the semiconductor package described referring to FIGS. 1 to 29 may be applied to an electronic system 2100. The electronic system 2100 may include a body 2110, a microprocessor unit 2120, a power unit 2130, a function unit 2140, and a display controller unit 2150. The body 2110 may be a mother board formed of a printed circuit board (PCB). The microprocessor unit 2120, the power unit 2130, the function unit 2140, and the display controller unit 2150 may be mounted on the body 2110. A display unit 2160 may be installed inside or outside of the body 2110. For example, the display unit 2160 may be installed on the surface of body 2110 to display an image processed by display controller unit 2150.

The power unit 2130 may function to receive a constant voltage from an external battery (not shown), divide the voltage into required levels, and supply those voltages to the microprocessor unit 2120, the function unit 2140, and the display controller unit 2150, etc. The microprocessor unit 2120 may receive a voltage from the power unit 2130 to control the function unit 2140 and the display unit 2160. The function unit 2140 may perform various functions of an electronic system 2100. For example, if the electronic system 2100 is a cellular phone, the function unit 2140 may have several components which can perform functions of a cellular phone such as dialing, outputting images to the display unit 2160 by communicating with an external apparatus 2170, and outputting sounds to a speaker. If a camera is installed, the function unit 2140 may function as a camera image processor.

According to example embodiments, when the electronic system 2100 is connected to a memory card, etc. in order to expand capacity, the function unit 2140 may be a memory card controller. The function unit 2140 may exchange signals with the external apparatus 2170 through a wired or wireless communication unit 2180. Further, when the electronic system 2100 needs a universal serial bus (USB) in order to expand functionality, the function unit 2140 may perform as an interface controller. In addition, the function unit 2140 may include a mass storage device.

The semiconductor package described referring to FIGS. 1 to 29 can be applied to the function unit 2140 or the microprocessor unit 2120. For example, the microprocessor unit 2120 may include the first heat dissipation pattern 29 and the second heat dissipation pattern 32. Due to the configurations of the first heat dissipation pattern 29 and the second heat dissipation pattern 32, the microprocessor unit 2120 may be formed lighter, thinner, shorter, and/or smaller, and shows improved heat dissipation characteristics compared to conventional ones. Accordingly, the electric characteristics of the electronic system 2100 may be significantly improved as compared to the conventional system.

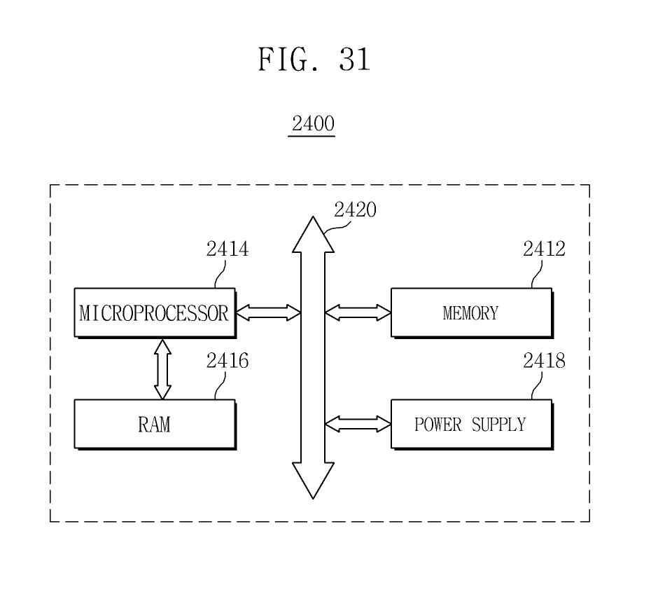

FIG. 31 is a block diagram schematically illustrating another electronic system 2400 which includes at least one of the semiconductor packages in accordance with example embodiments of the inventive concepts.

Referring to FIG. 31, the electronic system 2400 may include at least one of the semiconductor packages in accordance with example embodiments of the inventive concepts. The electronic system 2400 may be used to fabricate a mobile apparatus or a computer. For example, the electronic system 2400 may include a memory system 2412, a microprocessor 2414, a RAM 2416, and a power supply 2418. The microprocessor 2414 may program and control the electronic system 2400. The RAM 2416 may be used as an operation memory of the microprocessor 2414. The microprocessor 2414, the RAM, and/or other components can be assembled in a single package. The memory system 2412 may store codes for operating the microprocessor 2414, data processed by the microprocessor 2414, or external input data. The memory system 2412 may include a controller and a memory.

The semiconductor package described referring to FIGS. 1 to 29 can be applied to the microprocessor 2414, the RAM 2416, or the memory system 2412. For example, the microprocessor 2414 may include the first heat dissipation pattern 29 and the second heat dissipation pattern 32. Due to the configurations of the first heat dissipation pattern 29 and the second heat dissipation pattern 32, the microprocessor 2414 may be lighter, thinner, shorter and/or smaller, and may have improved heat dissipation characteristics compared to conventional ones. Accordingly, the electric characteristics of the electronic system 2400 can be significantly improved as compared to the conventional system.

According to example embodiments of the inventive concepts, a semiconductor chip and a first heat dissipation pattern are mounted on a PCB. A second heat dissipation pattern having a TIM is formed between the semiconductor chip and the first heat dissipation pattern. Accordingly, a semiconductor package capable of reducing or minimizing thickness and efficiently dissipating heat can be realized.

The foregoing is illustrative of example embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of the inventive concepts as defined in the claims. In the claims, means-plus-function clauses are intended to cover the structures described herein as performing the recited function, and not only structural equivalents but also equivalent structures.

What is claimed is:

1. A semiconductor package, comprising:
a semiconductor chip on a substrate;
a first heat dissipation pattern on the substrate, the first heat dissipation pattern having an opening therein, and the opening configured to expose the semiconductor chip; and
a second heat dissipation pattern between a side surface of the semiconductor chip and the first heat dissipation pattern, the second heat dissipation pattern including a thermal interface material (TIM).

2. The semiconductor package according to claim 1, wherein a top surface of the second heat dissipation pattern has a relatively high mean curvature compared to a top surface of the semiconductor chip.

3. The semiconductor package according to claim 1, wherein a top surface of the second heat dissipation pattern is either higher or lower than a top surface of the semiconductor chip.

4. The semiconductor package according to claim 1, wherein the first heat dissipation pattern is thicker than the semiconductor chip.

5. The semiconductor package according to claim 1, wherein a top surface of the first heat dissipation pattern is higher than a top surface of the semiconductor chip.

6. The semiconductor package according to claim 1, wherein the first heat dissipation pattern includes at least one of a through-hole and a groove, and the opening of the first heat dissipation pattern is in communication with an outside of the first heat dissipation pattern via the through-hole and/or the groove.

7. The semiconductor package according to claim 1, wherein the semiconductor chip includes a first side surface, a second side surface facing the first side surface, and a heating circuit close to the first side surface, wherein a first gap between the first side surface and the first heat dissipation pattern is narrower than a second gap between the second side surface and the first heat dissipation pattern.

8. The semiconductor package according to claim 1, further comprising:
a filler between the substrate and the semiconductor chip; and
an internal terminal through the filler, the internal terminal electrically connecting the semiconductor chip to the substrate,
wherein the internal terminal includes a solder ball or a conductive bump, and the second heat dissipation pattern is in contact with the filler.

9. The semiconductor package according to claim 1, further comprising:
an internal terminal between the substrate and the semiconductor chip,
wherein the second heat dissipation pattern extends between the substrate and the semiconductor chip, and the internal terminal being through the second heat dissipation pattern, the internal terminal electrically connecting the semiconductor chip to the substrate.

10. The semiconductor package according to claim 1, wherein the second heat dissipation pattern extends between the first heat dissipation pattern and the substrate.

11. A semiconductor package, comprising:
a semiconductor chip on a substrate
an encapsulant on the substrate, the encapsulant configured to cover a side surface of the semiconductor;
a first heat dissipation pattern on the semiconductor chip and the encapsulant; and
a second heat dissipation pattern between the semiconductor chip and the first heat dissipation pattern and between the encapsulant and the first heat dissipation pattern, the second heat dissipation pattern including a thermal interface material (TIM).

12. The semiconductor package according to claim 11, wherein the second heat dissipation pattern is in contact with the semiconductor chip and the first heat dissipation pattern.

13. The semiconductor package according to claim 11, wherein the second heat dissipation pattern has a first thickness between the semiconductor chip and the first heat dissipation pattern, and a second thickness between the encapsulant and the first heat dissipation pattern, wherein the second thickness is greater than the first thickness.

14. The semiconductor package according to claim 11, wherein a top surface of the encapsulant is lower than a top surface of the semiconductor chip, and the second heat dissipation pattern is in contact with a side surface of the semiconductor chip.

15. The semiconductor package according to claim 11, wherein the first heat dissipation pattern includes an opening on the semiconductor chip, and the second heat dissipation pattern extends to an inside of the opening.

16. A semiconductor package, comprising:
a semiconductor chip on a substrate;
a first heat dissipation pattern on the substrate; and
a second heat dissipation pattern between the semiconductor chip and the first heat dissipation pattern, the second heat dissipation pattern including a thermal interface material (TIM).

17. The semiconductor package according to claim 16, wherein the first heat dissipation pattern includes an opening, the opening configured to expose the semiconductor chip.

18. The semiconductor package according to claim 16, wherein the second heat dissipation pattern extends at least one of between the substrate and the semiconductor chip and between the substrate and the first heat dissipation pattern.

19. The semiconductor package according to claim 16, wherein a top surface of the first heat dissipation pattern is either higher or lower than a top surface of the semiconductor chip.

20. The semiconductor package according to claim 19, wherein a bottom surface of the first heat dissipation pattern is lower than a bottom surface of the semiconductor chip, the bottom surface of the first heat dissipation pattern facing the substrate and being opposite to the top surface of the first heat dissipation pattern, and the bottom surface of the semiconductor chip facing the substrate and being opposite to the top surface of the semiconductor chip.
